(19) United States
(12) Patent Application Publication
(10) Pub. No.: US 2021/0381096 A1
(43) Pub. Date: Dec. 9, 2021

(54) APPARATUS FOR VAPOR JET DEPOSITION AND METHOD FOR MANUFACTURING VAPOR JET NOZZLE UNIT

(71) Applicants: Samsung Display Co., LTD., Yongin-si (KR); Korea Advanced Institute of Science and Technology, Daejeon (KR)

(72) Inventors: Ganyoung PARK, Hwaseong-si (KR); Sung Yeon KIM, Daejeon (KR); Seung Hyup YOO, Daejeon (KR)

(73) Assignees: Samsung Display Co., LTD., Yongin-si (KR); Korea Advanced Institute of Science and Technology, Daejeon (KR)

(21) Appl. No.: 17/339,318

(22) Filed: Jun. 4, 2021

(30) Foreign Application Priority Data
Jun. 5, 2020 (KR) 10-2020-0068213

(51) Int. Cl. C23C 14/24

(52) U.S. Cl. CPC C23C 14/24

(57) ABSTRACT

An apparatus for vapor jet deposition includes a source vapor generation part generating a source vapor, and a nozzle part including a diffusion block diffusing the source vapor, a nozzle plate including a plurality of nozzles, and a coupling member disposed between the diffusion block and the nozzle plate to combine the diffusion block with the nozzle plate. A thermal expansion coefficient of the coupling member has a value between a thermal expansion coefficient of the diffusion block and a thermal expansion coefficient of the nozzle plate. The coupling member includes a glass material. A softening temperature of the coupling member is equal to or less than about 400° C.

### CROSS-REFERENCE TO RELATED APPLICATION(S)

This application claims priority to and the benefit of Korean Patent Application No. 10-2020-0068213 under 35 U.S.C. § 119, filed in the Korean Intellectual Property Office (KIPO) on Jun. 5, 2020, the entire contents of which are incorporated herein by reference.

### BACKGROUND

### 1. Technical Field

The disclosure relates to an apparatus for deposition. More specifically, the disclosure relates to an apparatus for vapor jet deposition and a method for manufacturing a vapor jet nozzle unit.

### 2. Description of the Related Art

Recently, organic electronic devices using organic electronic materials such as an organic light-emitting diode, an organic semiconductor element, an organic sensor element or the like are being increased.

Vacuum evaporation is being widely used for depositing an organic thin film. However, it is required that a substrate and a vapor source are spaced apart from each other by a sufficient distance to form a uniform organic thin film through vacuum evaporation. Thus, in case that a desired size of an organic thin film is increased, an effective usage rate of a source material may be reduced, and a required size of a vacuum chamber may be increased. Furthermore, since a shadow mask, which is used to form an organic thin film pattern, needs to be disposed on a vapor source, sagging of the shadow mask may cause irregular patterns.

In order to solve the above problems, vapor jet deposition is being developed and researched. According to the vapor jet deposition, an organic source material is vaporized, and sprayed as a jet.

### SUMMARY

Embodiments provide an apparatus for vapor jet deposition which may form a large-sized organic thin film and have increased reliability.

Embodiments provide a method for manufacturing a vapor jet nozzle unit.

According to an embodiment, an apparatus for vapor jet deposition according to an embodiment may include a source vapor generation part generating a source vapor, and a nozzle part including a diffusion block diffusing the source vapor, a nozzle plate including a plurality of nozzles, and a coupling member disposed between the diffusion block and the nozzle plate to combine the diffusion block with the nozzle plate. A thermal expansion coefficient of the coupling member may have a value between a thermal expansion coefficient of the diffusion block and a thermal expansion coefficient of the nozzle plate. The coupling member may include a glass material. A softening temperature of the coupling member may be equal to or less than about 400° C.

In an embodiment, the source vapor may include an organic material.

In an embodiment, the apparatus further may include a transporting gas supply part providing a transporting gas to the source vapor generation part.

In an embodiment, the diffusion block may include a thermal expansion inhibition alloy including at least iron and nickel.

In an embodiment, the thermal expansion coefficient of the coupling member may be greater than about 2.6 ppm/° C. and smaller than about 5 ppm/° C.

In an embodiment, a glass transition temperature and a softening temperature of the coupling member may be about 300° C. to about 350° C., respectively.

In an embodiment, the coupling member may be formed of a glass frit having a low melting temperature.

In an embodiment, the diffusion block may include a diffusion flow path connected to at least one of the plurality of nozzles.

In an embodiment, the coupling member may include a via portion connecting the diffusion flow path to at least one of the plurality of nozzles.

In an embodiment, the plurality of nozzles may pass through the nozzle plate, and a length-to-diameter ratio of the nozzles may be equal to or greater than 5:1.

In an embodiment, a diameter of the plurality of nozzles at a vapor-entering surface may be smaller than a diameter of the plurality of nozzles at a vapor-discharging surface.

In an embodiment, the nozzle plate may include silicon.

In an embodiment, the plurality of nozzles may be arranged in a first direction.

In an embodiment, the plurality of nozzles may be arranged in a first direction and in a second direction intersecting the first direction.

In an embodiment, the plurality of nozzles may be arranged in a zigzag configuration.

According to an embodiment, a method for manufacturing a vapor jet nozzle unit may include coating a glass frit including a frit powder is coated on a diffusion block including a diffusion flow path to form a frit layer including a via portion which forms the diffusion flow path, disposing a nozzle plate including a plurality of nozzles on the frit layer so that the nozzle plate contacts the frit layer, heating the frit layer to form a coupling member which combines the diffusion block with the nozzle plate. A thermal expansion coefficient of the coupling member may have a value between a thermal expansion coefficient of the diffusion block and a thermal expansion coefficient of the nozzle plate. A softening temperature of the coupling member may be equal to or less than about 400° C.

In an embodiment, the diffusion block may include a thermal expansion inhibition alloy including at least iron and nickel.

The thermal expansion coefficient of the coupling member may be greater than about 2.6 ppm/° C. and smaller than about 5 ppm/° C.

A glass transition temperature and a softening temperature of the coupling member may be about 300° C. to about 350° C., respectively.

The nozzle plate includes silicon, and a length-to-diameter ratio of the plurality of nozzles may be equal to or greater than 5:1.

According to embodiments, a diffusion block and a nozzle plate which have different materials, may be stably bonded with each other, and bonding failures due to thermal expansion difference between the diffusion block and the nozzle plate may be reduced or prevented. Thus, a large-sized vapor jet deposition may be achieved.

Furthermore, linearity of a vapor jet may be increased thereby increasing a resolution of printed patterns.

### BRIEF DESCRIPTION OF THE DRAWINGS

Aspects of one or more embodiments of the disclosure will be more clearly understood from the following detailed description taken in conjunction with the accompanying drawings.

FIG. 1 is a schematic diagram illustrating an apparatus for vapor jet deposition according to an embodiment.

FIG. 2 is a schematic perspective view illustrating an apparatus for vapor jet deposition according to an embodiment.

FIG. 3 is a schematic cross-sectional view illustrating a nozzle part of an apparatus for vapor jet deposition according to an embodiment.

FIG. 4 is a schematic rear view illustrating a nozzle part of an apparatus for vapor jet deposition according to an embodiment.

FIGS. 5 and 6 are schematic rear views illustrating a nozzle part of an apparatus for vapor jet deposition according to embodiments.

FIGS. 7, 8, 9, 10 and 11 are schematic cross-sectional views illustrating a method for manufacturing a vapor jet nozzle unit according to an embodiment.

FIG. 12 is a schematic cross-section view illustrating a nozzle plate of an apparatus for vapor jet deposition according to an embodiment.

FIGS. 13, 14 and 15 are schematic cross-sectional views illustrating a nozzle part of an apparatus for vapor jet deposition according to embodiments.

FIG. 16 is a schematic diagram illustrating an apparatus for vapor jet deposition according to an embodiment.

### DETAILED DESCRIPTION OF THE EMBODIMENTS

An apparatus for vapor jet deposition according to embodiments of the disclosure will be described hereinafter with reference to the accompanying drawings.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

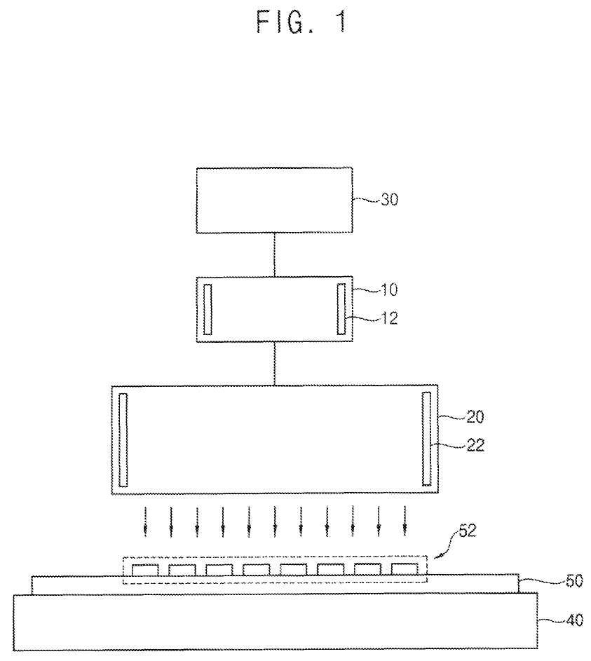

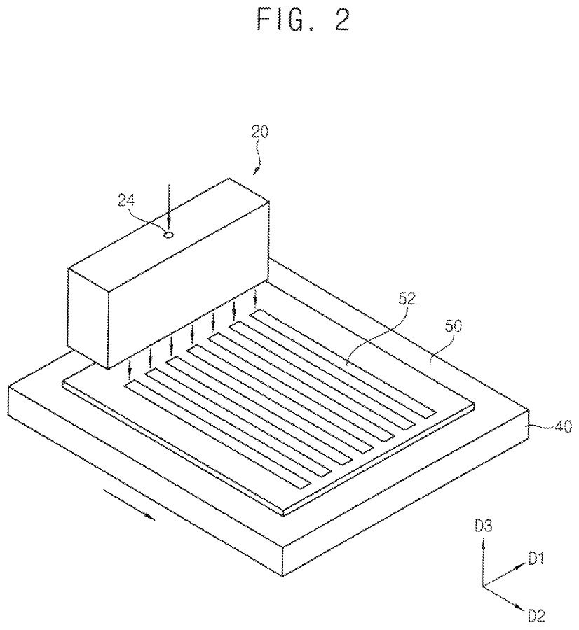

FIG. 1 is a schematic diagram illustrating an apparatus for vapor jet deposition according to an embodiment. FIG. 2 is a schematic perspective view illustrating an apparatus for vapor jet deposition according to an embodiment.

Referring to FIGS. 1 and 2, an apparatus for vapor jet deposition according to an embodiment includes a source vapor generation part 10 and a nozzle part 20, which receives a source vapor from the source vapor generation part 10 and discharges the source vapor.

For example, the nozzle part 20 may discharge the source vapor to a substrate 50 disposed on a stage 40 to form an organic thin film pattern 52 on the substrate 50. For example, the nozzle part 20 may include nozzles, and organic thin film patterns corresponding to the nozzles may be formed.

The apparatus for vapor jet deposition may further include a transporting gas supply part 30, which provides a transporting gas to the source vapor generation part 10. For example, the transporting gas may include an inert gas such as argon gas, nitrogen gas, helium gas, or the like. The transporting gas supply part 30 may be further connected to the nozzle part 20 to provide a transporting gas to the nozzle part 20, thereby adjusting a concentration and a pressure of the source vapor discharged from the nozzle part 20.

For example, the source vapor may include an organic material. For example, the source vapor may include various materials for forming an organic layer of an organic light-emitting diode, such as a hole-transporting material, a hole-injecting material, a light-emitting host material, a light-emitting dopant material, an electron-transporting material, an electron-injecting material, or the like. However, embodiments are not limited thereto. For example, the source vapor may include a precursor material for forming a metal layer, a metal oxide layer, a metal nitride layer, an insulation layer or the like.

The source vapor may be formed by vaporization of a solid source material or a liquid source material. The source vapor generation part 10 may include a heater 12 to generate the source vapor.

The source vapor may be transferred to the nozzle part 20 by the transporting gas. Thus, the source vapor may be discharged with the transporting gas to the substrate 50 from the nozzle part 20. The nozzle part 20 may include a connection portion 24 into which the source vapor flows. The nozzle part 20 may further include a heater 22 to heat the source vapor.

The nozzle part 20 includes nozzles. In an embodiment, the nozzles may be arranged in a first direction D1 The nozzle part 20 may be disposed on the substrate 50. For example, the nozzle part 20 may be spaced apart from the substrate 50 in a vertical direction.

While the source vapor is sprayed to an upper surface of the substrate 50, the substrate 50 may be moved in a second direction D2 intersecting the first direction D1 by the stage 40. Thus, organic thin film patterns 52 may be formed on the substrate 50. The organic thin film patterns 52 may be spaced apart from each other in the first direction D1. The organic thin film patterns 52 may have a shape extending in the second direction D2. However, embodiments are not limited thereto. For example, a position of the substrate 50 may be fixed, and the nozzle part 20 may move and spray the source vapor to form the organic thin film patterns 52.

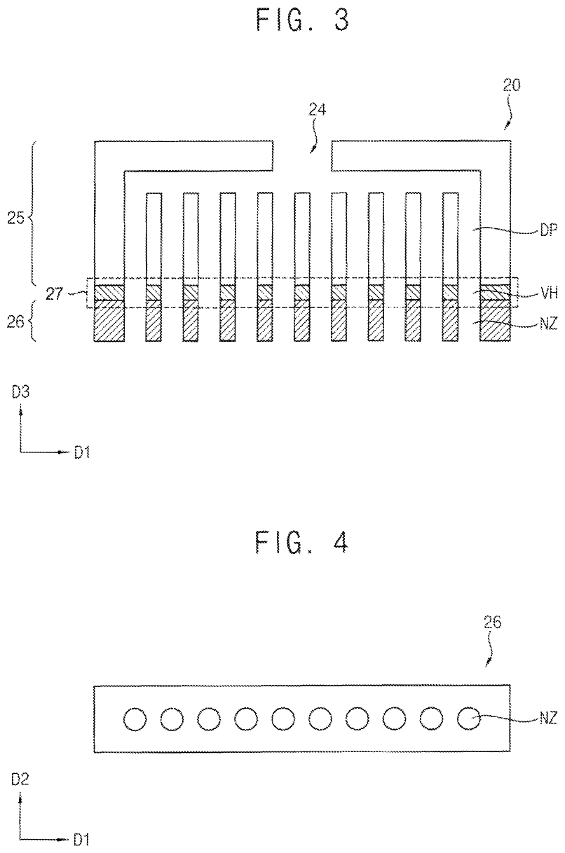

FIG. 3 is a schematic cross-sectional view illustrating a nozzle part of an apparatus for vapor jet deposition according to an embodiment. FIG. 4 is a schematic rear view illustrating a nozzle part of an apparatus for vapor jet deposition according to an embodiment.

Referring to FIGS. 3 and 4, a nozzle par 20 includes a diffusion block 25, a nozzle plate 26, and a coupling member 27 disposed between the diffusion block 25 and the nozzle plate 26.

The diffusion block 25 diffuses a source vapor transferred to the nozzle part 20, and transfers the diffused source vapor to the nozzle plate 26. The nozzle plate 26 includes nozzles NZ spaced apart from each other in a first direction D1. The nozzles NZ may pass through the nozzle plate 26. The diffusion block 25 may include diffusion flow paths DP respectively connected to the nozzles NZ. The diffusion flow paths DP may extend in the third direction, in which the nozzle NZ passes through the nozzle plate 26, to be connected to the nozzles NZ.

The diffusion block 25 includes a metal. For example, the diffusion block 25 may include a material having a relatively small thermal expansion coefficient, such as an iron-nickel-cobalt alloy, an iron-nickel alloy, titanium, or the like. For example, the diffusion block 25 may include a thermal expansion inhibition alloy such as Kovar®, Invar 36®, which are product names, or the like. In an embodiment, a material of the diffusion block 25 may have a thermal expansion coefficient equal to or less than about 7 ppm/° C.

In an embodiment, the nozzle plate 26 may include silicon. The nozzles NZ of the nozzle plate 26 may be arranged in the first direction D1. For example, a thickness of the nozzle plate 26 may be about 50 pm to about 1,000 pm.

The coupling member 27 may include a via portion VH, which connects the diffusion flow path DP of the diffusion block 25 to the nozzle NZ of the nozzle plate 26. Referring to FIG. 3, the diffusion flow path DP of the diffusion block 25, the nozzle NZ of the nozzle plate 26 and the via portion VH of the coupling member 27 may have a substantially same diameter. However, the embodiments are not limited thereto. For example, the diffusion flow path DP of the diffusion block 25, the nozzle NZ of the nozzle plate 26 and the via portion VH of the coupling member 27 may have different diameters from each other.

Furthermore, the diffusion flow path DP of the diffusion block 25, the nozzle NZ of the nozzle plate 26 and the via portion VH of the coupling member 27 may not be connected with one-to-one correspondence. For example, one via portion VH may be connected to at least two nozzles NZ, or one diffusion flow path DP may be connected to at least two nozzles NZ.

In an embodiment, the coupling member 27 may include a glass material. For example, the coupling member 27 may be formed of a glass frit. In case that the coupling member 27 is formed of a glass frit, the diffusion block 25 may be stably bonded or attached to the nozzle plate 26 without an additional process for reducing a surface roughness of the diffusion block 25 or the nozzle plate 26. Furthermore, after glass transition of the coupling member 27, outgas may not be caused at a temperature lower than a glass transition temperature. Furthermore, differences of thermal expansion coefficients between the coupling member 27 and the diffusion block 25 and between the coupling member 27 and the nozzle plate 26 are relatively small. Thus, damage or breakdown by thermal expansion difference may be reduced or prevented after the bonding process is performed.

Referring to FIG. 4, the nozzles NZ of the nozzle plate 26 may be arranged in the first direction Dl. However, the embodiments are not limited thereto, and nozzles of a nozzle plate may be variously arranged as desired.

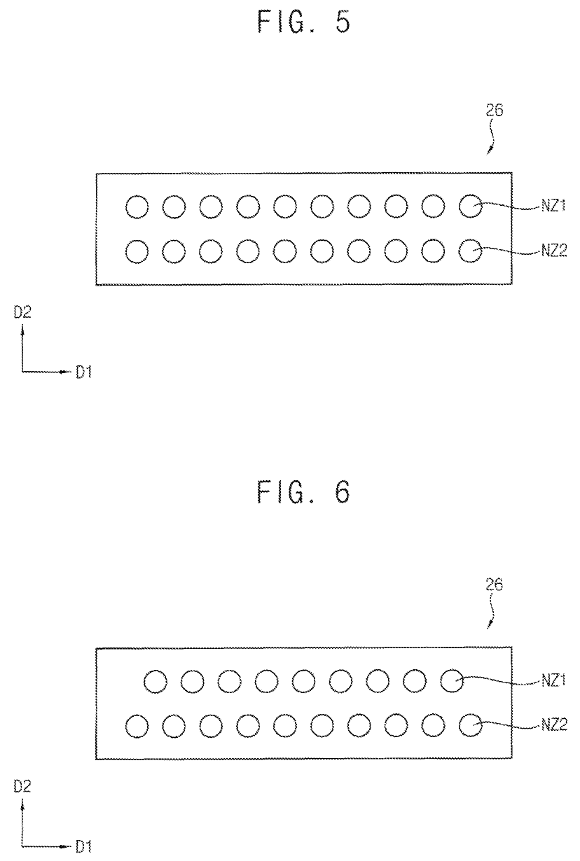

For example, referring to FIG. 5, a nozzle plate 26 may include first nozzles NZ1 arranged in a first direction D1, and second nozzles NZ2, which are spaced apart from the first nozzles NZ1 in a second direction D2 intersecting the first direction D1 and are arranged in the first direction Dl.

Referring to FIG. 6, a nozzle plate 26 may include first nozzles NZ1 arranged in a first direction D1, and second nozzles NZ2, which are spaced apart from the first nozzles NZ1 in a second direction D2 intersecting the first direction D1 and are arranged in the first direction D1. The first nozzles NZ1 and the second nozzles NZ2 may be arranged in a zigzag configuration.

For example, a diameter of the nozzles may be about 1 pm to about 100 pm. The nozzles may have various shapes such as a circular shape, an oval shape, a polygonal shape, or the like. However, the embodiments are not limited thereto. The nozzles may have various diameters and various shapes as desired.

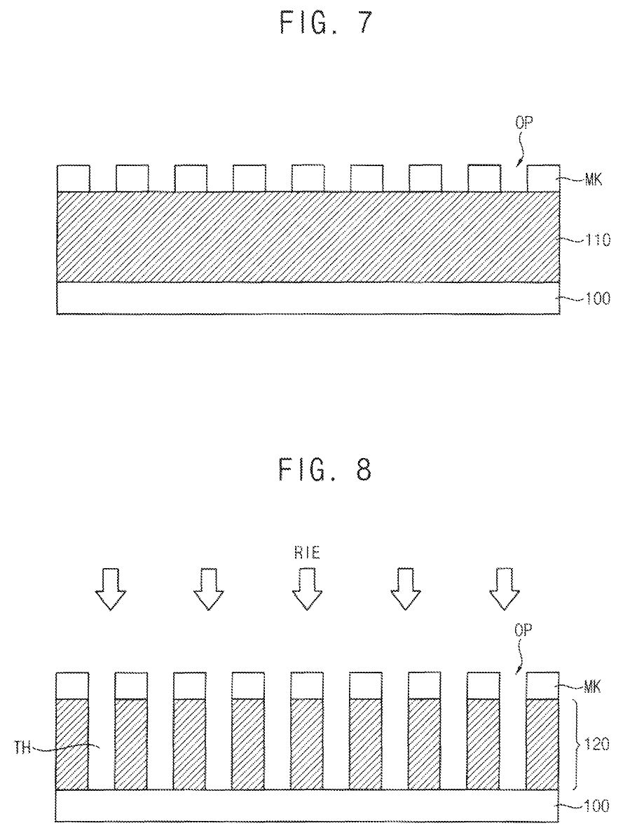

FIGS. 7, 8, 9, 10 and 11 are schematic cross-sectional view illustrating a method for manufacturing a vapor jet nozzle unit according to an embodiment. The vapor jet nozzle unit may correspond to the nozzle part 20 illustrated in FIGS. 1 to 3.

Referring to FIG. 7, a mask MK is disposed n a silicon base 110. The mask MK may include openings OP corresponding to nozzles.

The silicon body 110 may include amorphous silicon, multi-crystalline silicon or the like. The silicon body 110 may be disposed on a substrate 100.

Referring to FIG. 8, a portion of the silicon body 110, which is exposed through or in the openings OP of the mask MK, is etched to form a silicon plate 120 including a through hole TH. The silicon plate 120 may be used for a nozzle plate 26 illustrated in FIGS. 3 and 4.

In an embodiment, the through hole TH of the silicon plate 120 may be formed by an isotropic etching method. For example, the through hole TH of the silicon plate 120 may be formed by an reactive ion etching (RIE) method such as deep reactive ion etching (DRIE). The through hole TH formed by the isotropic etching method may have a large length-to-diameter ratio. Thus, in case that the silicon plate 120 is used as a nozzle plate for vapor jet deposition, the linearity of vapor jet may be increased so that a fine pattern with a high resolution may be obtained.

For example, a length-to-diameter ratio for the through hole (nozzle) may be equal to or greater than about 5:1. In case that a length-to-diameter ratio for the through hole is less than about 5:1, the linearity of vapor jet may be hardly increased. For example, a length-to-diameter ratio for the through hole may be about 5:1 to about 30:1.

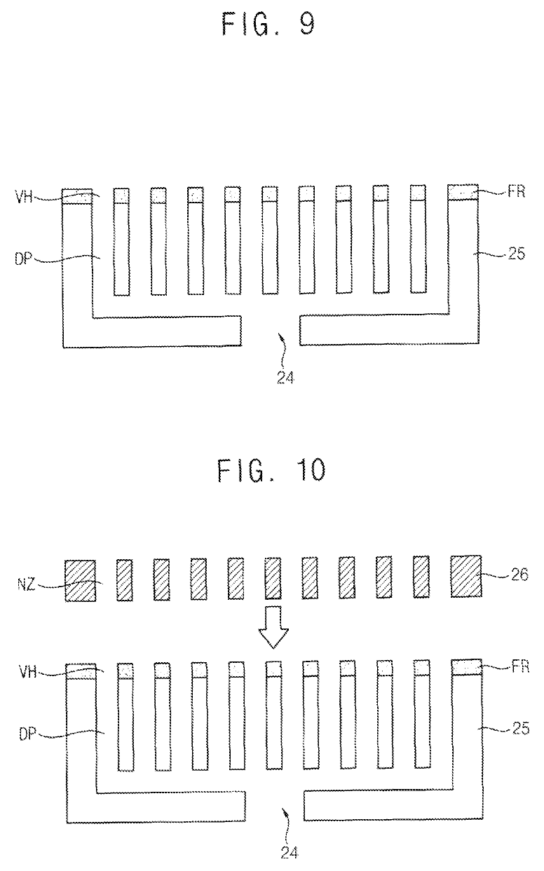

FIGS. 9 to 11 schematically illustrates a process of bonding a nozzle plate to a diffusion block.

Referring to FIG. 9, a glass frit is coated on a diffusion block 25 to form a frit layer FR. For example, the diffusion block 25 may include a material having a relatively small thermal expansion coefficient, such as an iron-nickel-cobalt alloy, an iron-nickel alloy, titanium, or the like.

In an embodiment, the glass frit may have a relatively low melting temperature. The glass frit of low melting temperature may stably bond (or attach) the diffusion block 25 and the nozzle plate, which have different materials from each other. Furthermore, a coupling member formed of the glass frit of a low melting temperature may form a stable bonding interface so that leakage of a source vapor may be prevented. Furthermore, since a bonding process may be performed at a relatively low temperature, thermal damage to the diffusion block 25 and the nozzle plate may be prevented. Furthermore, in deposition processes following the bonding process, the coupling member may not generate outgas because the coupling member is stable at a deposition temperature, for example, about 200° C. to about 300° C. Thus, contamination of a source vapor may be prevented.

For example, the glass frit of low melting temperature may include a frit powder, an organic binder, and an organic solvent.

For example, the frit powder may include P₂O₅, V₂O₅, ZnO, BaO, Sb₂O₃, Fe₂O₃, Al₂O₃, B₂O₃, Bi₂O₃, TiO₂, or a combination thereof. For example, a particle size of the frit powder may be about 0.1 μm to about 20 μm.

For example, the organic binder may include ethyl cellulose, ethylene glycol, propylene glycol, ethylhydroxyethylcellulose, a phenolic resin, an ester-based polymer, a methacrylate-based polymer, monobutylether of ethylene glycol monoacetate, or a combination thereof. The organic binder may be decomposed at a temperature lower than a temperature at which the frit powder is sintered.

For example, the organic solvent may include butyl carbitol acetate (BCA), α-terpineol (α-TPN), dibutyl phthalate (DBP), ethyl acetate, β-terpineol, cyclohexanone, cyclopentanone, hexylene glycol, alcohol ester, or a combination thereof.

The glass frit of low melting temperature may further include a filler. For example, the filler ay include cordierite, zircon, aluminum titanate, alumina, mullite, silica, α-quartz, glass, cristobalite, tridymite, tin oxide ceramic, β-spodumene, zirconium phosphate ceramic, β-quartz, or a combination thereof.

The glass frit of low melting temperature may further include a plasticizer, a releasing agent, a dispersion agent, an antifoaming agent, a leveling agent, a wetting agent, or a combination thereof, as desired.

For example, the glass frit may be provided on the diffusion block 25 by a screen printing method, a doctor blade, a dispenser, or the like.

The frit layer FR may be formed on a vapor-discharging surface of the diffusion block 25. The frit layer FR may include a via portion VH or may be partially formed on the vapor-discharging surface to open a diffusion flow path DP of the diffusion block 25.

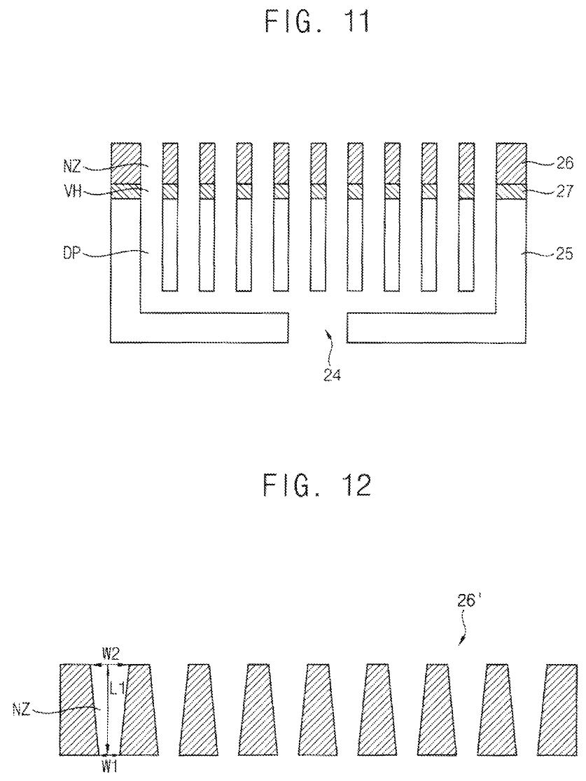

Referring to FIGS. 10 and 11, the nozzle plate 26 is disposed to contact an upper surface of the frit layer FR and then heated to form a coupling member 27 including a glassy material. The frit layer FR may be heated by a heater, a laser, or the like. In the process of heating the frit layer FR, the frit powder is densified and sintered to form the coupling member 27.

A thermal expansion coefficient of the coupling member 27 may be greater than a thermal expansion coefficient of the nozzle plate 26 and smaller than a thermal expansion coefficient of the diffusion block 25 to reduce a stress applied to the nozzle unit. For example, a thermal expansion coefficient of the coupling member 27 may be greater than about 2.6 ppm/° C. and smaller than about 5 ppm/° C.

Furthermore, a softening temperature of the coupling member 27 formed from the glass frit of low melting temperature may be equal to or less than about 400° C. For example, a glass transition temperature and a softening temperature of the coupling member 27 may be about 300° C. to about 350° C., respectively.

In an embodiment, the glass frit may be coated on the diffusion block 25. However, the embodiments are not limited thereto. For example, the glass frit may be coated on the nozzle plate 25.

According to embodiments, a diffusion block and a nozzle plate, which include different materials, may be stably bonded with each other, and bonding failures due to thermal expansion difference between the diffusion block and the nozzle plate may be reduced or prevented. Thus, a large-sized vapor jet deposition may be achieved. Furthermore, linearity of a vapor jet may be increased thereby increasing a resolution of printed patterns.

FIG. 12 is a schematic cross-sectional view illustrating a nozzle plate of an apparatus for vapor jet deposition according to an embodiment.

Referring to FIG. 12, a nozzle plate 26′ may include nozzles NZ, which pass through the nozzle plate 26′ and are arranged in a direction. The nozzles NZ may have different diameters at a vapor-entering surface and a vapor-discharging surface. For example, a diameter W1 of the nozzle NZ at the vapor-discharging surface may be smaller than a diameter W2 of the nozzle NZ at the vapor-discharging surface.

In an embodiment, a length-to-diameter ratio of the nozzle NZ, which is a ratio of the length L1 to the diameter W1 at the vapor-discharging surface, may be equal to or greater than 5:1. For example, a ratio of the length L1 to the diameter W1 at the vapor-discharging surface may be about 5:1 to about 30:1.

Referring to FIG. 13, a nozzle part 20 includes a diffusion block 25, a nozzle plate 26, and a coupling member 27 disposed between the diffusion block 25 and the nozzle plate 26.

The diffusion block 25 diffuses a source vapor transferred to the nozzle part 20 and transfers the diffused source vapor to the nozzle plate 26. The nozzle plate 26 includes nozzles NZ spaced apart from each other in a first direction D1. The nozzles NZ may pass through the nozzle plate 26. The diffusion block 25 may include diffusion flow paths DP respectively connected to the nozzles NZ. The diffusion flow paths DP may extend in the third direction D3, in which the nozzle NZ passes through the nozzle plate 26, to be connected to the nozzles NZ.

In an embodiment, a diffusion flow path DP may be connected to at least two nozzles NZ. The coupling member 27 may include a via portion VH connected to the diffusion flow path DP and the at least two nozzles NZ.

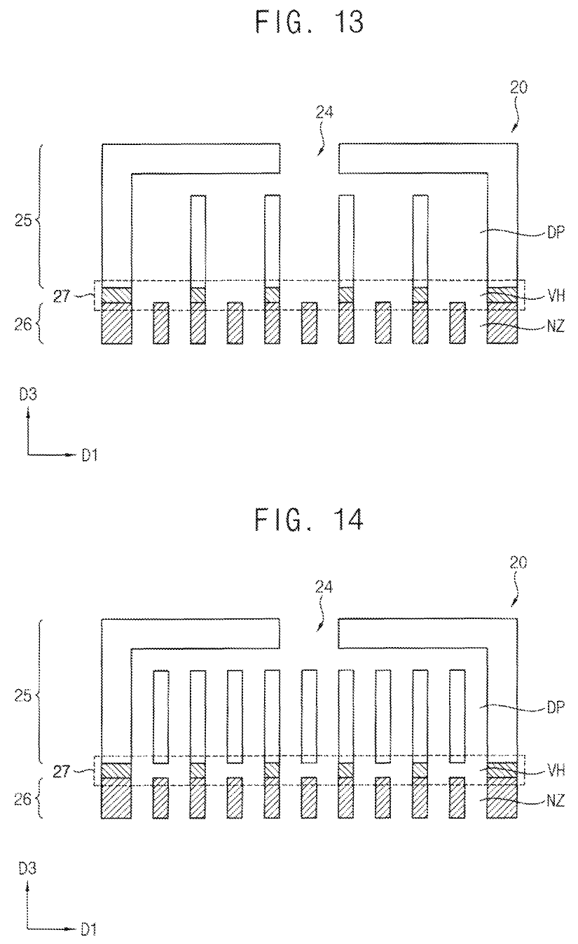

As illustrated in FIG. 14, a coupling member 27 may include via portions VH, and one via portion VH may be connected to at least two diffusion flow paths DP and at least two nozzles NZ.

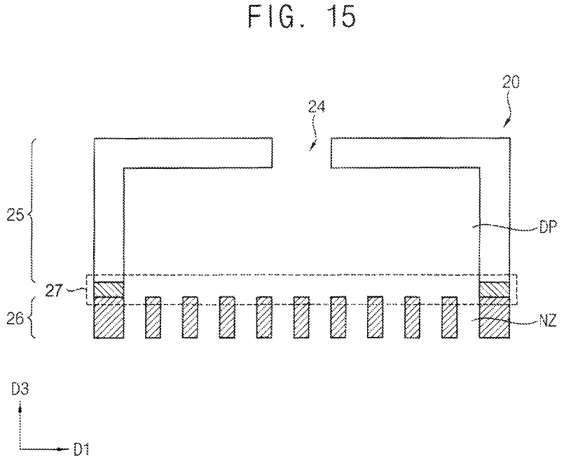

The embodiments are not limited to a diffusion block including diffusion flow paths. For example, as illustrated in FIG. 15, a diffusion block 25 may include a common diffusion flow path DP commonly connected to nozzles NZ of a nozzle plate 26. Thus, a coupling member 27 may be disposed along an edge of a lower surface of the diffusion block 25.

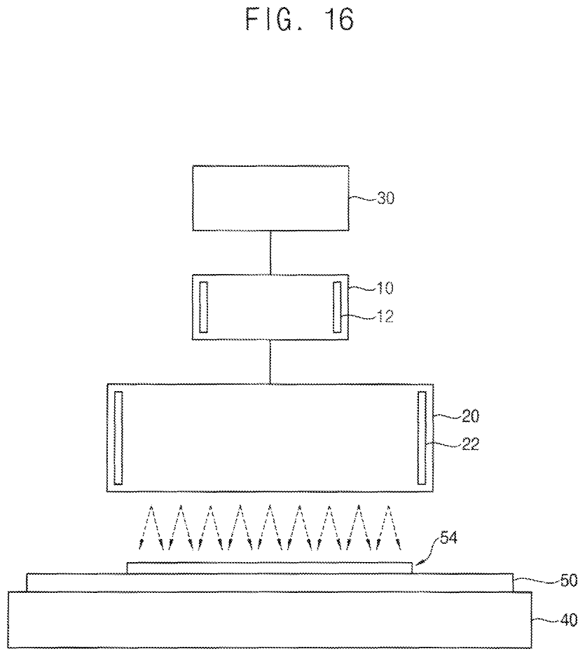

Referring to FIG. 16, an apparatus for vapor jet deposition according to an embodiment may form a large-sized organic thin film 54 using nozzles. For example, a distance between adjacent nozzles, a distance between the nozzles and a substrate 50, a linearity of a source vapor, or the like may be adjusted to overlap areas where the source vapor is sprayed on the substrate 50 thereby forming the large-sized organic thin film 54.

The embodiments may be used for forming an organic thin film. For example, the embodiment may be used for manufacturing various organic electronic devices such as an organic light-emitting diode, an organic semiconductor, an organic solar cell, an organic sensor or the like.

The foregoing is illustrative of embodiments and is not to be construed as limiting thereto. Although embodiments have been described, those skilled in the art will readily appreciate that many modifications are possible without materially departing from the novel teachings and aspects of the disclosure. Accordingly, all such modifications are intended to be included within the scope of the disclosure. Therefore, it is to be understood that the foregoing is illustrative of various embodiments and is not to be construed as limited to the specific embodiments disclosed, and that modifications to the disclosed embodiments, as well as other embodiments, are intended to be included within the scope of the disclosure.

What is claimed is:

1. An apparatus for vapor jet deposition, the apparatus comprising:
a source vapor generation part generating a source vapor; and
a nozzle part including:
a diffusion block diffusing the source vapor;
a nozzle plate including a plurality of nozzles; and
a coupling member disposed between the diffusion block and the nozzle plate to combine the diffusion block with the nozzle plate, wherein
a thermal expansion coefficient of the coupling member has a value between a thermal expansion coefficient of the diffusion block and a thermal expansion coefficient of the nozzle plate,
the coupling member includes a glass material, and
a softening temperature of the coupling member is equal to or less than about 400° C.

2. The apparatus of claim 1, wherein the source vapor includes an organic material.

3. The apparatus of claim 1, further comprising a transporting gas supply part providing a transporting gas to the source vapor generation part.

4. The apparatus of claim 1, wherein the diffusion block includes a thermal expansion inhibition alloy including at least iron and nickel.

5. The apparatus of claim 1, wherein the thermal expansion coefficient of the coupling member is greater than about 2.6 ppm/° C. and smaller than about 5 ppm/° C.

6. The apparatus of claim 1, wherein a glass transition temperature and a softening temperature of the coupling member are about 300° C. to about 350° C., respectively.

7. The apparatus of claim 1, wherein the coupling member is formed of a glass frit having a low melting temperature.

8. The apparatus of claim 1, wherein the diffusion block includes a diffusion flow path connected to at least one of the plurality of nozzles.

9. The apparatus of claim 8, wherein the coupling member includes a via portion connecting the diffusion flow path to at least one of the plurality of nozzles.

10. The apparatus of claim 1, wherein
the plurality of nozzles pass through the nozzle plate, and
a length-to-diameter ratio of the plurality of nozzles is equal to or greater than 5:1.

11. The apparatus of claim 1, wherein a diameter of the plurality of nozzles at a vapor-entering surface is smaller than a diameter of the plurality of nozzles at a vapor-discharging surface.

12. The apparatus of claim 1, wherein the nozzle plate includes silicon.

13. The apparatus of claim 1, wherein the plurality of nozzles are arranged in a first direction.

14. The apparatus of claim 1, wherein the plurality of nozzles are arranged in a first direction and in a second direction intersecting the first direction.

15. The apparatus of claim 14, wherein the plurality of nozzles are arranged in a zigzag configuration.

16. A method for manufacturing a vapor jet nozzle unit, comprising:
coating a glass frit including a frit powder on a diffusion block including a diffusion flow path to form a frit layer including a via portion which forms the diffusion flow path;
disposing a nozzle plate including a plurality of nozzles on the frit layer so that the nozzle plate contacts the frit layer; and
heating the frit layer to form a coupling member which combines the diffusion block with the nozzle plate, wherein
a thermal expansion coefficient of the coupling member has a value between a thermal expansion coefficient of the diffusion block and a thermal expansion coefficient of the nozzle plate, and
a softening temperature of the coupling member is equal to or less than about 400° C.

17. The method of claim 16, wherein the diffusion block includes a thermal expansion inhibition alloy including at least iron and nickel.

18. The method of claim 16, wherein the thermal expansion coefficient of the coupling member is greater than about 2.6 ppm/° C. and smaller than about 5 ppm/° C.

19. The method of claim 16, wherein a glass transition temperature and a softening temperature of the coupling member is about 300° C. to about 350° C., respectively.

20. The method of claim 16, wherein
the nozzle plate includes silicon, and
a length-to-diameter ratio of the plurality of nozzles is equal to or greater than 5:1.
